(19) United States
(12) Patent Application Publication
(10) Pub. No.: US 2026/0039289 A1
(43) Pub. Date: Feb. 5, 2026

(54) ELECTRONIC CIRCUITRY, DRIVE CIRCUIT, AND DETERMINATION METHOD

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takeshi UENO, Kawasaki (JP); Takuya HIRAKAWA, Yokohama (JP); Hiroki WATANABE, Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/288,612

(22) Filed: Aug. 1, 2025

(30) Foreign Application Priority Data
Aug. 2, 2024 (JP) 2024-128145

(51) Int. Cl. H03K 17/16; H03K 17/06

(52) U.S. Cl. CPC H03K 17/165; H03K 17/063; H03K 2217/0063; H03K 2217/0072

(57) ABSTRACT

According to one embodiment, an electronic circuitry includes a processing circuitry configured to determine a current polarity being a polarity of a current flowing through at least one of a first switching element and a second switching element, based on a first voltage between a first electrode and a second electrode of the first switching element during a dead time of a half-bridge circuit, the half-bridge circuit including the first switching element and the second switching element.

### CROSS REFERENCE TO RELATED APPLICATIONS

This application is based upon and claims the benefit of priority from the prior Japanese Patent Application No. 2024-128145, filed on Aug. 2, 2024, the entire contents of which are incorporated herein by reference.

### FIELD

Embodiments relate to an electronic circuitry, a drive circuit, and a determination method.

### BACKGROUND

A half-bridge circuit including two switching elements is used in various technical fields. For example, on-off waveforms of drive currents that are supplied to each switching element of the half-bridge circuit are controlled, and thereby, a half-bridge inverter can be configured. The switching of the switching elements causes the generation of electromagnetic noise (EMI: Electro-Magnetic Interference). The magnitude of the generated EMI has a correlation with the time for the transition from the on-state to the off-state or the transition from the off-state to the on-state in the switching element, and the EMI is smaller as the transition time is longer. Meanwhile, when the transition time is long, the loss that is generated in the switching element increases. Therefore, it is necessary to adjust the trade-off between the EMI and the loss.

As a method for the adjustment of the trade-off, there is a method of determining the current polarity of each switching element during the operation of the half-bridge inverter and adjusting the drive power of a gate driver depending on the determination result. As a configuration for determining the current polarity of the switching element, there is a method of determining the current polarity based on whether the voltage between a drain and a source changes within a predetermined determination time from the start timing of turn-off of the switching element. However, in this method, a timer is necessary for setting the determination time, and therefore, there is a problem in that the circuit configuration is complicated. Further, the determination time needs to be adjusted depending on the switching element, and therefore, there is also a problem in that the man-hour for the design of the gate driver is increased.

### BRIEF DESCRIPTION OF THE DRAWINGS

FIG. 1 is a diagram showing the configuration of a half-bridge inverter according to Embodiment 1;

FIG. 2 is a time chart for describing of the operation of each switching element when an output current of a half-bridge circuit is positive;

FIG. 3 is a time chart for describing of the operation of each switching element when the output current of the half-bridge circuit is negative;

FIG. 4 is a diagram showing the detailed configuration of a high-side determiner;

FIG. 5 is a time chart for describing the operation of the high-side determiner when a drain current polarity of a high-side is positive;

FIG. 6 is a time chart for describing the operation of the high-side determiner when the drain current polarity of the high-side is negative;

FIG. 7 is a diagram showing the detailed configuration of a high-side supplier;

FIG. 8 is a diagram showing the detailed configuration of a low-side supplier;

FIG. 9 is a diagram showing the configuration of a half-bridge inverter according to Embodiment 2;

FIG. 10 is a diagram showing the detailed configuration of a low-side determiner;

FIG. 11 is a time chart for describing the operation of the low-side determiner when a drain current polarity of a low-side is positive;

FIG. 12 is a time chart for describing the operation of the low-side determiner when the drain current polarity of the low-side is negative;

FIG. 13 is a diagram showing the configuration of a half-bridge inverter according to Embodiment 3;

FIG. 14 is a diagram showing the configuration of a half-bridge inverter according to Embodiment 4;

FIG. 15 is a diagram showing the detailed configuration of a high-side supplier;

FIG. 16 is a diagram showing a measurement method for a turn-on slew rate;

FIG. 17 is a diagram showing a measurement method for a turn-off slew rate;

FIG. 18 is a diagram showing the detailed configuration of a low-side supplier; and

FIG. 19 is a diagram showing the configuration of a three-phase inverter according to Embodiment 5.

### DETAILED DESCRIPTION

According to one embodiment, an electronic circuitry includes a processing circuitry configured to determine a current polarity being a polarity of a current flowing through at least one of a first switching element and a second switching element, based on a first voltage between a first electrode and a second electrode of the first switching element during a dead time of a half-bridge circuit, the half-bridge circuit including the first switching element and the second switching element.

According to one embodiment, a drive circuit for a half-bridge circuit that includes a first switching element and a second switching element, the drive circuit includes: a first supplier configured to supply a first drive current to the first switching element; a second supplier configured to supply a second drive current to the second switching element; and a processing circuitry configured to determine a current polarity being a polarity of a current flowing through at least one of the first switching element and the second switching element, based on a first voltage between a first electrode and a second electrode of the first switching element during a dead time of the half-bridge circuit.

According to one embodiment, a determination method includes: determining a current polarity being a polarity of a current flowing through at least one of a first switching element and a second switching element, based on a first voltage between a first electrode and a second electrode of the first switching element during a dead time of a half-bridge circuit, the half-bridge circuit including the first switching element and the second switching element.

Embodiments will be described below with reference to the drawings. In the drawings, identical or corresponding elements are denoted by identical reference characters, and detailed descriptions are omitted when appropriate.

### Embodiment 1

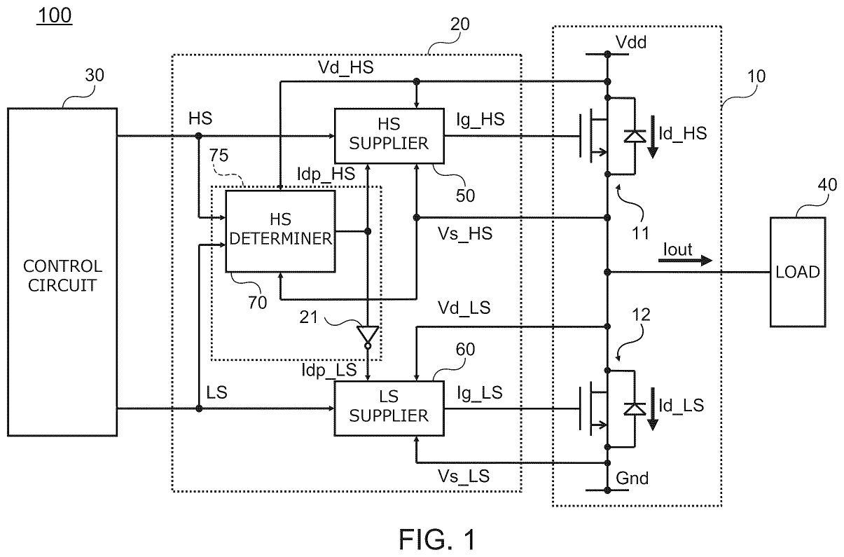

FIG. 1 is a diagram showing the configuration of a half-bridge inverter 100 according to Embodiment 1. The half-bridge inverter 100 includes a half-bridge circuit 10, a drive circuit 20, and a control circuit 30. A load 40 is connected to an output of the half-bridge inverter 100.

The half-bridge circuit 10 is constituted by a switching element 11 of a high-side and a switching element 12 of a low-side. As an example, each of the switching element 11 and the switching element 12 is an N-channel MOSFET (Metal Oxide Semiconductor Field Effect Transistor). Alternatively, each of the switching element 11 and the switching element 12 may be an IGBT (Insulated Gate Bipolar Transistor) or the like.

A drain of the switching element 11 of the high-side is connected to a power source voltage (a supply voltage) Vdd. A source of the switching element 11 of the high-side is connected to a drain of the switching element 12 of the low-side. A source of the switching element 12 of the low-side is connected to a ground Gnd. An output current Iout of the half-bridge circuit 10 is supplied to the load 40. As for the polarity of the output current Iout, a positive polarity is defined as the direction of the flow from the half-bridge circuit 10 to the load 40, and a negative polarity is defined as the direction of the flow from the load 40 to the half-bridge circuit 10. However, the definitions may be reversed.

The drive circuit 20 includes a high-side supplier 50, a low-side supplier 60, a sign inverter 21, and a high-side determiner 70. The high-side supplier 50 supplies a gate current Ig_HS to the switching element 11 of the high-side, in accordance with a high-side command signal HS that is input from the control circuit 30. The low-side supplier 60 supplies a gate current Ig_LS to the switching element 12 of the low-side, in accordance with a low-side command signal LS that is input from the control circuit 30.

Each of the high-side command signal HS and low-side command signal LS that are supplied from the control circuit 30 has two states: a high level (referred to as a Hi, hereinafter) as a first logic level and a low level (referred to as a Lo, hereinafter) as a second logic level. However, the correspondence of the first logic level and second logic level to the high level and low level may be reversed. As an example, the Hi is 5 V, and the Lo is 0 V. When the high-side command signal HS is the Hi, the high-side supplier 50 supplies the gate current Ig_HS to the switching element 11 of the high-side, so that the switching element 11 is turned on. When the high-side command signal HS is the Lo, the high-side supplier 50 supplies the gate current Ig_HS in the reverse direction, so that the switching element 11 is turned off. Similarly, when the low-side command signal LS is the Hi, the low-side supplier 60 supplies the gate current Ig_LS to the switching element 12 of the low-side, so that the switching element 12 is turned on. When the low-side command signal LS is the Lo, the low-side supplier 60 supplies the gate current Ig_LS in the reverse direction, so that the switching element 12 is turned off.

Further, the high-side supplier 50 controls the magnitude of the gate current Ig_HS, based on a voltage Vds_HS between the drain and the source in the switching element 11 of the high-side and a drain current polarity Idp_HS of the switching element 11 of the high-side that is input from the high-side determiner 70. Similarly, the low-side supplier 60 controls the magnitude of the gate current Ig_LS, based on a voltage Vds_LS between the drain and the source in the switching element 12 of the low-side and a drain current polarity Idp_LS of the switching element 12 of the low-side that is input from the sign inverter 21.

The high-side determiner 70 determines the drain current polarity Idp_HS of the switching element 11 of the high-side, based on the voltage Vds_HS between the drain and the source in the switching element 11 of the high-side during a dead time of the half-bridge circuit 10. The drain current polarity Idp_HS of the high-side has either a positive value (Hi) or a negative value (Lo). The positive value is defined as the direction of the flow of the drain current Id_HS of the switching element 11 of the high-side from the drain to the source, and the negative value is defined as the direction of the flow from the source to the drain. However, the definitions may be reversed. The high-side determiner 70 and the sign inverter 21 constitute a determination circuit (a processing circuitry) 75 that determines the current polarity of at least one of the switching element 11 of the high-side and the switching element 12 of the low-side.

The drain current polarity Idp_LS of the switching element 12 of the low-side also has either a positive value (Hi) or a negative value (Lo). When the positive value is defined as the direction of the flow of the drain current Id_LS of the switching element 12 of the low-side from the drain to the source, the drain current polarity Idp_LS constantly has the opposite sign of the drain current polarity Idp_HS of the high-side, because of the characteristic of the half-bridge circuit 10. That is, Idp_LS=−Idp_HS is constantly satisfied. The sign inverter 21 acquires the drain current polarity Idp_LS of the low-side, by inverting the sign of the drain current polarity Idp_HS of the high-side that is output from the high-side determiner 70.

The control circuit 30 supplies the high-side command signal HS and the low-side command signal LS to the drive circuit 20. The load 40 is an arbitrary electronic device or electric device that is driven by alternating-current power. For example, in the case where the load 40 is an alternating-current motor, the control circuit 30 supplies the high-side command signal HS and low-side command signal LS after PWM modulation, to the drive circuit 20. Alternatively, the half-bridge inverter 100 may be equipped in a power source apparatus such as a PV inverter for solar photovoltaic generation. In this case, the output of the half-bridge inverter is connected to an electric power grid, instead of the load 40.

The operation of each switching element of the half-bridge circuit 10 will be described, and the relation of the slew rate of a voltage Vds between the drain and the source in each switching element with the gate current Ig_HS and the gate current Ig_LS will be discussed.

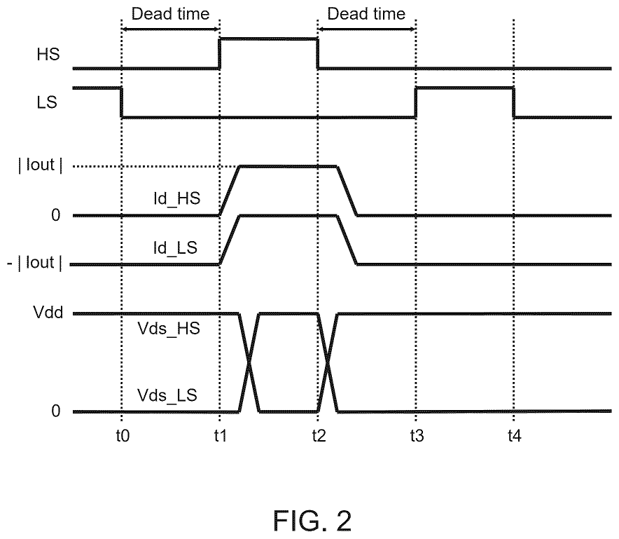

FIG. 2 is a time chart for describing the operation of each switching element when the output current Iout of the half-bridge circuit 10 is positive. When the output current Iout of the half-bridge circuit 10 is positive, electric current flows from the half-bridge circuit 10 to the load 40.

The low-side command signal LS becomes the Lo at time t0, and then, electric current is commutated to a parasitic diode of the switching element 12 of the low-side, although electric current flows from the source to the drain in the switching element 12 of the low-side before time t0. At this time, the drain current Id_LS of the switching element 12 of the low-side in a period of time t0 to time t1 is negative, and the value is −|Iout|. Further, when the forward voltage of the parasitic diode is ignored because of the conduction of the parasitic diode, the voltage Vds_LS between the drain and the source in the switching element 12 of the low side is 0. Since the positive direction of the drain current Id_LS is the direction of the flow from the drain to the source and the negative direction is the direction of the flow from the source to the drain, the value of the drain current is −| Iout|. However, since the positive direction of the output current Iout of the half-bridge circuit 10 is the direction of the flow to the load 40, the value of the output current Iout of the half-bridge circuit 10 at this time is |Iout| (positive value).

The high-side command signal HS becomes the Hi at time t1, and then, the electric current (Id_LS=−| Iout|) that flows through the parasitic diode of the switching element 12 of the low-side is commutated to between the drain and the source in the switching element 11 of the high-side. At this time, the drain current Id_HS of the switching element 11 of the high-side increases from 0 to Iout. Conversely, the drain current Id_LS of the switching element 12 of the low-side rises from −|Iout| to 0 (the absolute value decreases). The switching element 11 of the high-side is turned on, and therefore, the voltage Vds_HS between the drain and the source decreases from Vdd to 0. Conversely, the voltage Vds_LS between the drain and the source in the switching element 12 of the low-side rises from 0 to Vdd.

The high-side command signal HS becomes the Lo at time t2, and then, the electric current (Id_HS=Iout) that flows between the drain and the source in the switching element 11 of the high-side is commutated to the parasitic diode of the switching element 12 of the low-side. At this time, the drain current Id_LS of the switching element 12 of the low-side falls from 0 to −|Iout| (the absolute value increases). Conversely, the drain current Id_HS of the switching element 11 of the high-side decreases from Iout to 0. The switching element 11 of the high-side is turned off, and therefore, the voltage Vds_HS between the drain and the source rises from 0 to Vdd. Conversely, the voltage Vds_LS between the drain and the source in the switching element 12 of the low-side falls from Vdd to 0.

The low-side command signal LS becomes the Hi at time t3, and then, the electric current (Id_LS=−| Iout|) that flows through the parasitic diode of the switching element 12 of the low-side is commutated to between the source and the drain in the switching element 12 of the low-side. At this time, the drain current Id of each switching element and the voltage Vds between the drain and the source do not change.

The low-side command signal LS becomes the Lo at time t4, and then, the electric current (Id_LS=−| Iout|) that flows between the source and the drain in the switching element 12 of the low-side is commutated to the parasitic diode of the switching element 12 of the low-side. Also at this time, the drain current Id of each switching element and the voltage Vds between the drain and the source do not change.

As seen from FIG. 2, when the output current Iout of the half-bridge circuit 10 is positive, the change in the drain current Id of each switching element and the change in the voltage Vds between the drain and the source each are due to the change in the high-side command signal HS, and have no relation with the change in the low-side command signal LS. Accordingly, when the output current Iout of the half-bridge circuit 10 is positive, the slew rate of the voltage Vds between the drain and the source in each switching element depends on only the magnitude of the gate current Ig_HS of the high-side, and has no relation with the gate current Ig_LS of the low-side.

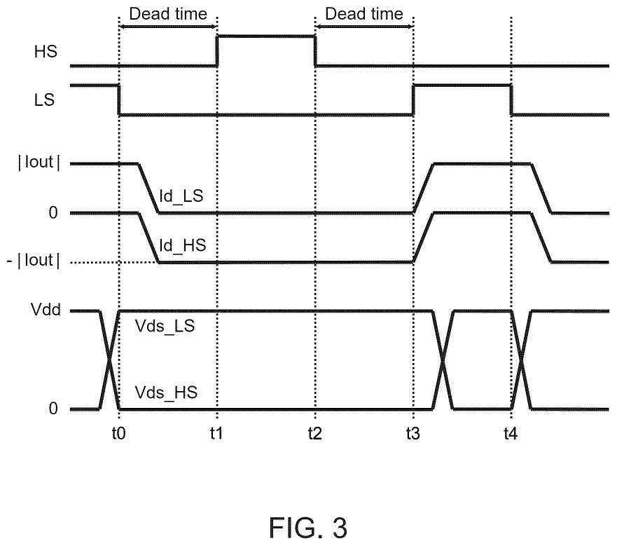

FIG. 3 is a time chart for describing the operation of each switching element when the output current Iout of the half-bridge circuit 10 is negative. When the output current Iout of the half-bridge circuit 10 is negative, electric current flows from the load 40 to the half-bridge circuit 10.

The low-side command signal LS becomes the Lo at time t0, and then, electric current is commutated to a parasitic diode of the switching element 11 of the high-side, although electric current flows from the drain to the source in the switching element 12 of the low-side before time t0. At this time, the drain current Id_HS of the switching element 11 of the high-side in a period of time t0 to time t1 is negative, and the value is −|Iout|. Further, when the forward voltage of the parasitic diode is ignored because of the conduction of the parasitic diode, the voltage Vds_HS between the drain and the source in the switching element 11 of the high-side is 0.

The high-side command signal HS becomes the Hi at time t1, and then, the electric current (Id_HS=−|Iout|) that flows through the parasitic diode of the switching element 11 of the high-side is commutated to between the source and the drain in the switching element 11 of the high-side. At this time, the drain current Id of each switching element and the voltage Vds between the drain and the source do not change.

The high-side command signal HS becomes the Lo at time t2, and then, the electric current (Id_HS=−|Iout|) that flows between the source and the drain in the switching element 11 of the high-side is commutated to the parasitic diode of the switching element 11 of the high-side again. Also at this time, the drain current Id of each switching element and the voltage Vds between the drain and the source do not change.

The low-side command signal LS becomes the Hi at time t3, and then, the electric current (Id_HS=−|Iout|) that flows through the parasitic diode of the switching element 11 of the high-side is commutated to between the drain and the source in the switching element 12 of the low-side. At this time, the drain current Id_LS of the switching element 12 of the low-side increases from 0 to Iout. Conversely, the drain current Id_HS of the switching element 11 of the high-side rises from −|Iout| to 0 (the absolute value decreases). The switching element 12 of the low-side is turned on, and therefore, the voltage Vds_LS between the drain and the source falls from Vdd to 0. Conversely, the voltage Vds_HS between the drain and the source in the switching element 12 of the high-side rises from 0 to Vdd.

The low-side command signal LS becomes the Lo at time t4, and then, the electric current (Id_LS=Iout) that flows between the drain and the source in the switching element 12 of the low-side is commutated to the parasitic diode of the switching element 11 of the high-side. At this time, the drain current Id_HS of the switching element 11 of the high-side falls from 0 to −|Iout| (the absolute value increases). Conversely, the drain current Id_LS of the switching element 12 of the low-side decreases from Iout to 0. The switching element 12 of the low-side is turned off, and therefore, the voltage Vds_LS between the drain and the source rises from 0 to Vdd. Conversely, the voltage Vds_HS between the drain and the source in the switching element 11 of the high-side falls from Vdd to 0.

As seen in FIG. 3, when the output current Iout of the half-bridge circuit 10 is negative, the change in the drain current Id of each switching element and the change in the voltage Vds between the drain and the source each are due to the change in the low-side command signal LS, and have no relation with the change in the high-side command signal HS. Accordingly, when the output current Iout of the half-bridge circuit 10 is negative, the slew rate of the voltage Vds between the drain and the source of in each switching element depends on only the magnitude of the gate current Ig_LS of the low-side, and has no relation with the gate current Ig_HS of the high-side.

From the result in FIG. 2 and FIG. 3, for controlling the slew rate of the voltage Vds between the drain and the source in each switching element, it is only necessary to adjust the magnitude of the gate current Ig_HS of the high-side when the output current Iout of the half-bridge circuit 10 is positive, and it is only necessary to adjust the magnitude of the gate current Ig_LS of the low-side when the output current Iout of the half-bridge circuit 10 is negative.

Further, with reference to FIG. 2, when the output current Iout of the half-bridge circuit 10 is positive, the drain current Id_HS of the high-side is constantly 0 or more, and the drain current Id_LS of the low-side is constantly 0 or less. In other words, when the output current Iout of the half-bridge circuit 10 is positive, the drain current polarity Idp_HS of the high-side is constantly positive (Hi), and the drain current polarity Idp_LS of the low-side is constantly negative (Lo).

On the other hand, with reference to FIG. 3, when the output current Iout of the half-bridge circuit 10 is negative, the drain current Id_HS of the high-side is constantly 0 or less, and the drain current Id_LS of the low-side is constantly 0 or more. In other words, when the output current Iout of the half-bridge circuit 10 is negative, the drain current polarity Idp_HS of the high-side is constantly negative (Lo), and the drain current polarity Idp_LS of the low-side is constantly positive (Hi).

From the above discussion, for controlling the slew rate of the voltage Vds between the drain and the source in each switching element, it is only necessary to control the gate current Ig of the switching element when the drain current polarity Idp is positive (Hi). Specifically, the high-side supplier 50 only needs to control the magnitude of the gate current Ig_HS, only when the drain current polarity Idp_HS of the high-side is positive (Hi). On the other hand, the low-side supplier 60 only needs to control the magnitude of the gate current Ig_LS, only when the drain current polarity Idp_LS of the low-side is positive (Hi).

Next, the principle of the determination of the drain current polarity Idp_HS of the high-side by the high-side determiner 70 will be described. As described above, the high-side determiner 70 determines the drain current polarity Idp_HS of the high-side, based on the voltage Vds_HS between the drain and the source in the switching element 11 of the high-side during the dead time of the half-bridge circuit 10.

In FIG. 2 and FIG. 3, the dead time of the half-bridge circuit 10, that is, periods in which both of the high-side command signal HS and the low-side command signal LS are the Lo, specifically, a period of time t0 to time t1 and a period of time t2 to time 3 will be particularly described.

In the case of FIG. 2, that is, when the drain current polarity Idp_HS of the high-side is positive, the voltage Vds_HS between the drain and the source of the high-side, in the period of time t0 to time t1, is continuously Vdd. In the period of time t2 to time t3, the voltage Vds_HS between the drain and the source of the high-side is continuously Vdd after the shift from 0 to Vdd immediately after time t2.

On the other hand, in the case of FIG. 3, that is, when the drain current polarity Idp_HS of the high-side is negative, the voltage Vds_HS between the drain and the source of the high-side, in the period of time to to time t1, is continuously 0 after the shift from Vdd to 0 immediately after time t0. In the period of time t2 to time t3, the voltage Vds_HS between the drain and the source of the high-side is continuously 0.

From the above result, in the case where the voltage Vds_HS between the drain and the source in the switching element 11 of the high-side is Vdd during the dead time, the drain current polarity Idp_HS of the high-side is positive. On the other hand, in the case where the voltage Vds_HS between the drain and the source in the switching element 11 of the high-side is 0 during the dead time, the drain current polarity Idp_HS of the high-side is negative. Accordingly, the high-side determiner 70 can determine the drain current polarity Idp_HS of the high-side by checking whether the voltage Vds_HS between the drain and the source in the switching element 11 of the high-side during the dead time is Vdd or 0.

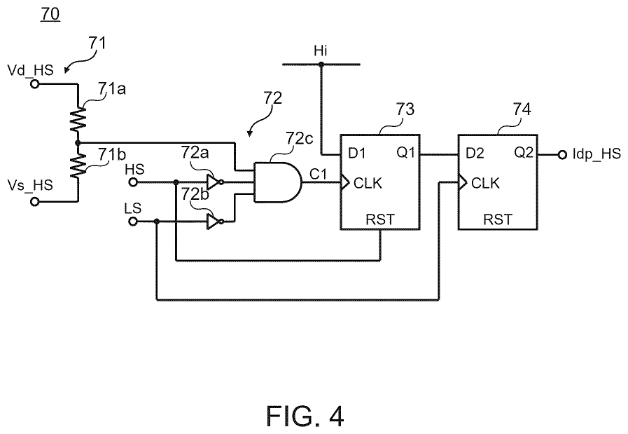

FIG. 4 is a diagram showing the detailed configuration of the high-side determiner 70. The high-side determiner 70 includes a voltage division circuit 71, a combinational logic circuit 72, a first flip-flop 73, and a second flip-flop 74.

The voltage division circuit 71 is constituted by a resistor 71a and a resistor 71b, and divides the voltage Vds_HS between the drain and the source of the high-side such that Vdd is the Hi and 0 is the Lo. As an example, the Hi is 5 V, and the Lo is 0 V. In the case where Vdd is lower than an input-allowable voltage of an AND gate 72c of the combinational logic circuit 72 described below, the voltage division circuit 71 may be excluded, and Vdd may be directly input to the AND gate 72c.

The combinational logic circuit 72 includes a NOT gate 72a, a NOT gate 72b, and the AND gate 72c with three inputs. An output C1 of the combinational logic circuit 72 becomes the Hi, only in the case where the half-bridge circuit 10 is in the state of the dead time and where the voltage Vds_HS between the drain and the source of the high-side is Vdd.

The Hi is constantly input to an input D1 of the first flip-flop 73. The output C1 of the combinational logic circuit 72 is input to a clock CLK of the first flip-flop 73. The high-side command signal HS is input to a reset RST of the first flip-flop 73. An output Q1 of the first flip-flop 73 is set to the Hi at a timing when the output C1 of the combinational logic circuit 72 becomes the Hi, and is reset to the Lo at a timing when the high-side command signal HS becomes the Hi.

The output Q1 of the first flip-flop 73 is input to an input D2 of the second flip-flop 74. The low-side command signal LS is input to a clock CLK of the second flip-flop 74. The second flip-flop 74 samples the value of Q1 at a timing when the low-side command signal LS becomes the Hi, and holds this value as an output Q2. The output Q2 of the second flip-flop 74 is an output of the high-side determiner 70. As described above, the high-side determiner 70 outputs either the positive value (Hi) or the negative value (Lo), as the drain current polarity Idp_HS of the high-side.

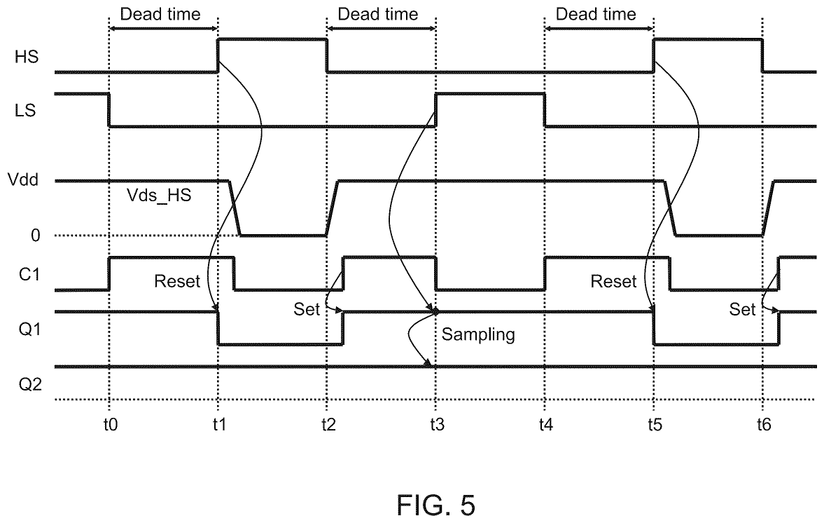

FIG. 5 is a time chart for describing the operation of the high-side determiner 70 when the drain current polarity Idp_HS of the high-side is positive. When the drain current polarity Idp_HS of the high-side is positive, the voltage Vds_HS between the drain and the source of the high-side changes due to the change in the high-side command signal HS.

The output Q1 of the first flip-flop 73 is reset to the Lo when the high-side command signal HS becomes the Hi at time t1 and time t5, and is set to the Hi when the output C1 of the combinational logic circuit 72 becomes the Hi immediately after time t2 and time t6. The second flip-flop 74 samples the value Hi of Q1 at a timing when the low-side command value LS becomes the Hi at time t3, and holds this value as the output Q2. Thereby, when the drain current polarity Idp_HS of the high-side is positive, the output of the high-side determiner 70 is constantly positive (Hi).

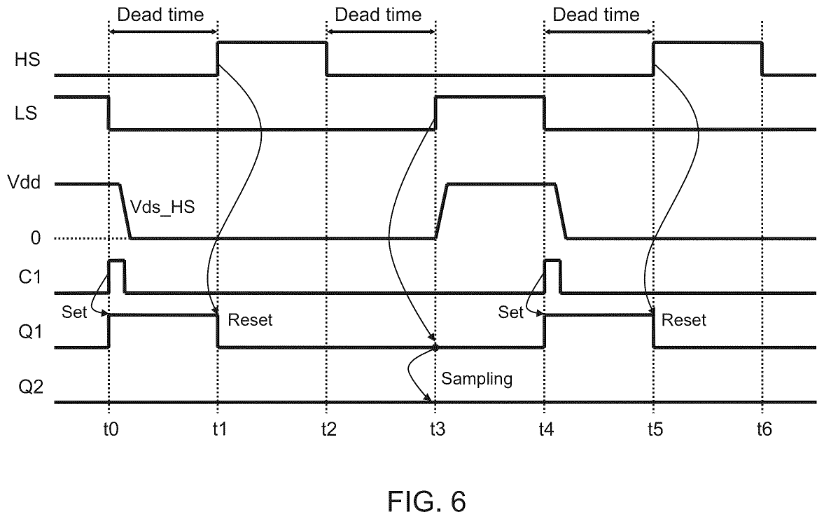

FIG. 6 is a time chart for describing the operation of the high-side determiner 70 when the drain current polarity Idp_HS of the high-side is negative. When the drain current polarity Idp_HS of the high-side is negative, the voltage Vds_HS between the drain and the source of the high-side changes due to the change in the low-side command signal LS.

The output Q1 of the first flip-flop 73 is set to the Hi when the output C1 of the combinational logic circuit 72 becomes the Hi at time to and time t4, and is reset to the Lo when the high-side command signal HS becomes the Hi at time t1 and time t5. The second flip-flop 74 samples the value Lo of Q1 at a timing when the low-side command signal LS becomes the Hi at time t3, and holds this value as the output Q2. Thereby, when the drain current polarity Idp_HS of the high-side is negative, the output of the high-side determiner 70 is constantly negative (Lo).

As described above, the high-side determiner 70 can determine the drain current polarity Idp_HS of the high-side, based on the high-side command signal HS, the low-side command signal LS, and the voltage Vds_HS between the drain and the source of the high-side.

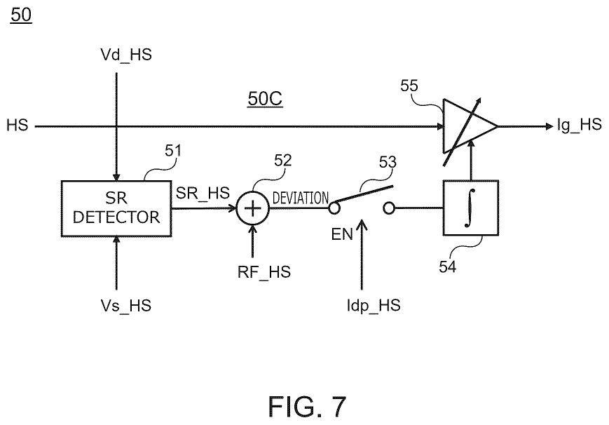

FIG. 7 is a diagram showing the detailed configuration of the high-side supplier 50. The high-side supplier 50 includes a slew rate detector 51, an adder 52, a switch 53, a compensator 54, and a current controller 55.

The slew rate detector 51 detects a slew rate SR_HS of the voltage Vds_HS between the drain and the source in the switching element 11 of the high-side. The adder 52 calculates the deviation between the slew rate SR_HS and a target value RF_HS. The switch 53 is turned on when the drain current polarity Idp_HS of the high-side is positive (Hi). The compensator 54 includes an integration element such as a capacitor, and integrates the output of the adder 52 when the switch 53 is in the on-state.

The current controller 55 supplies the gate current Ig_HS to the switching element 11 of the high-side, when the high-side command signal HS is the Hi. The current controller 55 controls the magnitude of the gate current Ig_HS, depending on the output of the compensator 54.

A high-side slew rate controller 50C is constituted by a feedback group that is formed by the slew rate detector 51, the adder 52, the switch 53, the compensator 54, and the current controller 55. When the drain current polarity Idp_HS of the high-side is positive (Hi), the high-side slew rate controller 50C controls the magnitude of the gate current Ig_HS such that the slew rate SR_HS of the high-side coincides with the target value RF_HS.

As described above, when the drain current polarity Idp_HS of the high-side is negative, the slew rate of the voltage Vds between the drain and the source in each switching element of the half-bridge circuit 10 depends on only the magnitude of the gate current Ig_LS of the low-side. In other words, when the drain current polarity Idp_HS of the high-side is negative, it makes no sense to control the magnitude of the gate current Ig_HS of the high-side, and further, consumed power increases. Therefore, by the function of the switch 53, the high-side slew rate controller 50C operates only when the drain current polarity Idp_HS of the high-side is positive (Hi).

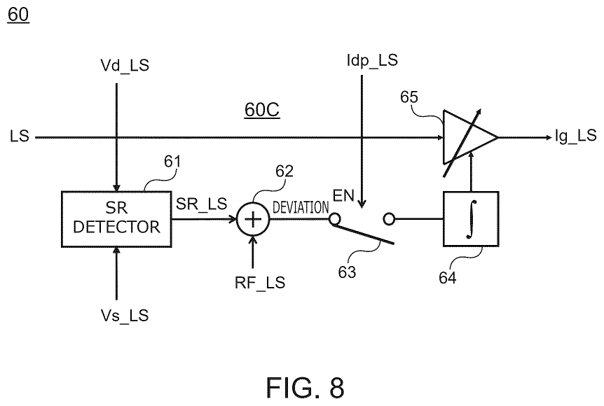

FIG. 8 is a diagram showing the detailed configuration of the low-side supplier 60. The low-side supplier 60 includes a slew rate detector 61, an adder 62, a switch 63, a compensator 64, and a current controller 65.

The slew rate detector 61 detects a slew rate SR_LS of the voltage Vds_LS between the drain and the source in the switching element 12 of the low-side. The adder 62 calculates the deviation between the slew rate SR_LS and a target value RF_LS. The switch 63 is turned on when the drain current polarity Idp_LS of the low-side is positive (Hi). The compensator 64 includes an integration element such as a capacitor, and integrates the output of the adder 62 when the switch 63 is in the on-state.

The current controller 65 supplies the gate current Ig_LS to the switching element 12 of the low-side, when the low-side command signal LS is the Hi. The current controller 65 controls the magnitude of the gate current Ig_LS, depending on the output of the compensator 64.

A low-side slew rate controller 60C is constituted by a feedback group that is formed by the slew rate detector 61, the adder 62, the switch 63, the compensator 64, and the current controller 65. When the drain current polarity Idp_LS of the low-side is positive (Hi), the low-side slew rate controller 60C controls the magnitude of the gate current Ig_LS such that the slew rate SR_LS of the low-side coincides with the target value RF_LS.

As described above, when the drain current polarity Idp_LS of the low-side is negative, the slew rate of the voltage Vds between the drain and the source in each switching element of the half-bridge circuit 10 depends on only the magnitude of the gate current Ig_HS of the high-side. In other words, when the drain current polarity Idp_LS of the low-side is negative, it makes no sense to control the magnitude of the gate current Ig_LS of the low-side, and further, consumed power increases. Therefore, by the function of the switch 63, the low-side slew rate controller 60C operates only when the drain current polarity Idp_LS of the low-side is positive (Hi).

As described above, the drive circuit 20 of the half-bridge inverter 100 according to Embodiment 1 includes the high-side determiner 70 that determines the drain current polarity Idp_HS of the switching element 11 of the high-side in the half-bridge circuit 10. The high-side determiner 70 determines the drain current polarity Idp_HS of the high-side, based on the voltage Vds_HS between the drain and the source in the switching element 11 of the high-side during the dead time of the half-bridge circuit 10. The sign inverter 21 acquires the drain current polarity Idp_LS of the low-side, by inverting the sign of the drain current polarity Idp_HS of the high-side.

Because of the above characteristic, the drive circuit 20 of the half-bridge inverter 100 according to Embodiment 1 can determine the drain current polarity Idp of each switching element included in the half-bridge circuit 10, from the voltage Vds_HS between the drain and the source in the switching element 11 of the high-side included in the half-bridge circuit 10.

Further, the high-side slew rate controller 50C is constituted by each constituent element included in the high-side supplier 50. The high-side slew rate controller 50C controls the magnitude of the gate current Ig_HS of the high-side, such that the slew rate SR_HS of the high-side coincides with the target value RF_HS. Similarly, the low-side slew rate controller 60C is constituted by each constituent element included in the low-side supplier 60. The low-side slew rate controller 60C controls the magnitude of the gate current Ig_LS of the low-side, such that the slew rate SR_LS of the low side coincides with the target value RF_LS.

As described above, when the drain current polarity Idp_HS of the high-side is positive, the slew rate of each switching element depends on only the magnitude of the gate current Ig_HS of the high-side, and has no relation with the magnitude of the gate current Ig_LS of the low-side. On the other hand, when the drain current polarity Idp_LS of the low-side is positive, the slew rate of each switching element depends on only the magnitude of the gate current Ig_LS of the low-side, and has no relation with the magnitude of the gate current Ig_HS of the high-side.

In consideration of the above characteristic, the high-side slew rate controller 50C operates only when the drain current polarity Idp_HS of the high-side is positive, and does not operate when the drain current polarity Idp_HS of the high-side is negative. Similarly, the low-side slew rate controller 60C operates only when the drain current polarity Idp_LS of the low-side is positive, and does not operate when the drain current polarity Idp_LS of the low-side is negative. Thereby, the gate current Ig that does not influence the slew rate is avoided from being needlessly controlled.

Further, in addition to the needless control and the increase in consumed power, the control of the gate current Ig that does not influence the slew rate occasionally causes an inefficient effect. For example, when the drain current polarity Idp_HS of the high-side is negative and the control of the gate current Ig_HS of the high-side that does not influence the slew rate is continued, there is a possibility that the gate current Ig_HS becomes excessively large or small. In this state, when the drain current polarity Idp_HS of the high-side changes from the negative value to the positive value and the control of the gate current Ig_HS is started, a control for restoring the gate current Ig_HS from the excessively large or small value to an adequate value is necessary. In Embodiment 1, it is possible to avoid such an inefficient control.

### Embodiment 2

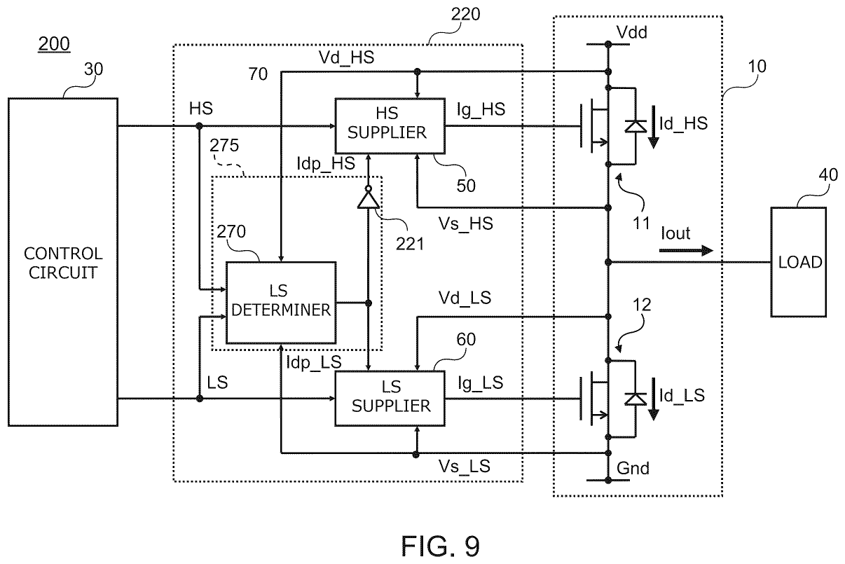

FIG. 9 is a diagram showing the configuration of a half-bridge inverter 200 according to Embodiment 2. A drive circuit 220 includes a low-side determiner 270, instead of the high-side determiner 70 in Embodiment 1. The low-side determiner 270 determines the drain current polarity Idp_LS of the switching element 12 of the low-side, based on the voltage Vds_LS between the drain and the source in the switching element 12 of the low-side during the dead time of the half-bridge circuit 10. A sign inverter 221 acquires the drain current polarity Idp_HS of the high-side, by inverting the sign of the drain current polarity Idp_LS of the low-side that is output from the low-side determiner 270. The low-side determiner 270 and the sign inverter 221 constitute a determination circuit (a processing circuitry) 275 that determines the current polarity of at least one of the switching element 11 of the high-side and the switching element 12 of the low-side.

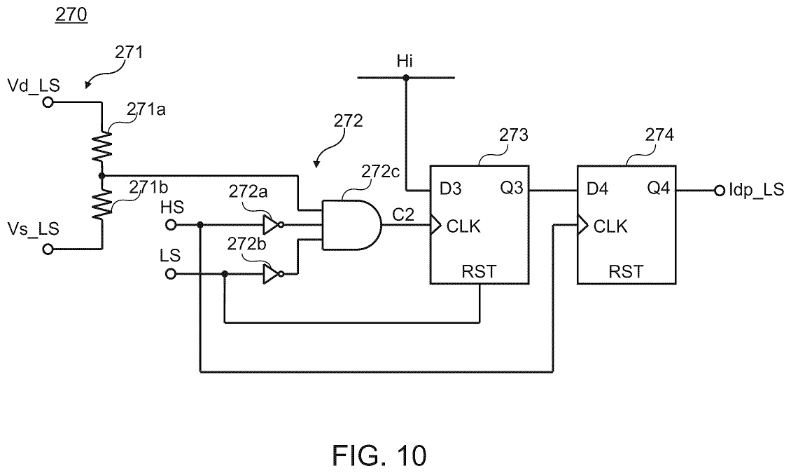

FIG. 10 is a diagram showing the detailed configuration of the low-side determiner 270. The low-side determiner 270 includes a voltage division circuit 271, a combinational logic circuit 272, a third flip-flop 273, and a fourth flip-flop 274.

The voltage division circuit 271 is constituted by a resistor 271a and a resistor 271b, and divides the voltage Vds_LS between the drain and the source of the low-side such that Vdd is the Hi and 0 is the Lo. As an example, the Hi is 5 V, and the Lo is 0 V.

The combinational logic circuit 272 includes a NOT gate 272a, a NOT gate 272b, and an AND gate 272c with three inputs. An output C2 of the combinational logic circuit 272 becomes the Hi, only in the case where the half-bridge circuit 10 is in the state of the dead time and where the voltage Vds_LS between the drain and the source of the low-side is Vdd.

The Hi is constantly input to an input D3 of the third flip-flop 273. The output C2 of the combinational logic circuit 272 is input to a clock CLK of the third flip-flop 273. The low-side command signal LS is input to a reset RST of the third flip-flop 273. An output Q3 of the third flip-flop 273 is set to the Hi at a timing when the output C2 of the combinational logic circuit 272 becomes the Hi, and is reset to the Lo at a timing when the low-side command signal LS becomes the Hi.

The output Q3 of the third flip-flop 273 is input to an input D4 of the fourth flip-flop 274. The high-side command signal HS is input to a clock CLK of the fourth flip-flop 274. The fourth flip-flop 274 samples the value of Q3 at a timing when the high-side command signal HS becomes the Hi, and holds this value as an output Q4. The output Q4 of the fourth flip-flop 274 is an output of the low-side determiner 270.

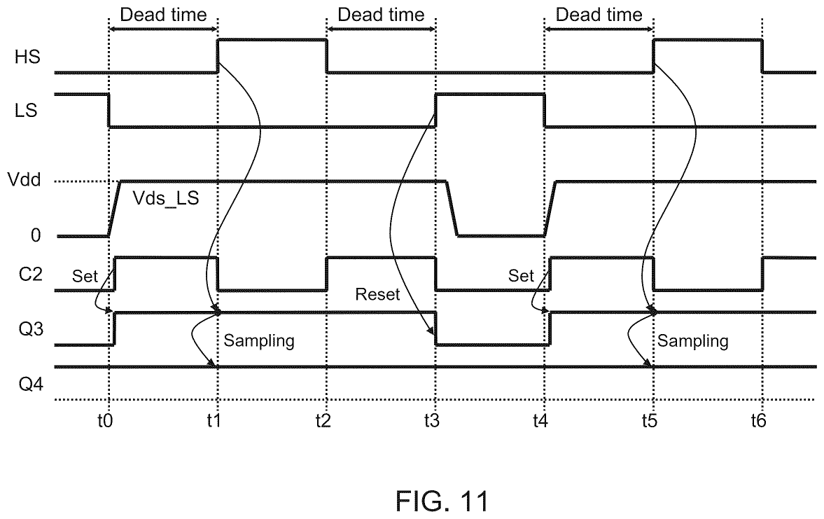

FIG. 11 is time chart for describing the operation of the low-side determiner 270 when the drain current polarity Idp_LS of the low-side is positive. When the drain current polarity Idp_LS of the low-side is positive, the voltage Vds_LS between the drain and the source of the low-side changes due to the change in the low-side command signal LS.

The output Q3 of the third flip-flop 273 is set to the Hi when the output C2 of the combinational logic circuit 272 becomes the Hi immediately after time t0 and time t4, and is reset to the Lo when the low-side command signal LS becomes the Hi at time t3. The fourth flip-flop 274 samples the value Hi of Q3 at timings when the high-side command signal HS becomes the Hi at time t1 and time t5, and holds this value as the output Q4. Thereby, when the drain current polarity Idp_LS of the low-side is positive, the output of the low-side determiner 270 is constantly positive (Hi).

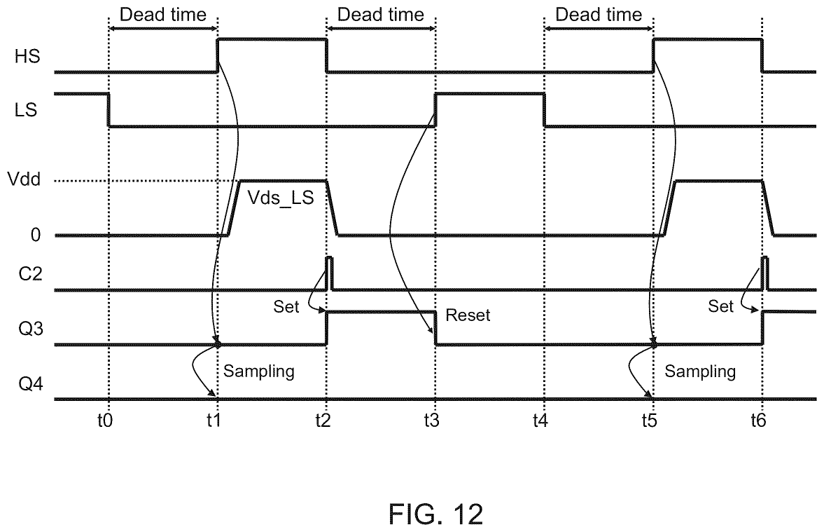

FIG. 12 is a time chart for describing the operation of the low-side determiner 270 when the drain current polarity Idp_LS of the low-side is negative. When the drain current polarity Idp_LS of the low-side is negative, the voltage Vds_LS between the drain and the source of the low-side changes due to the change in the high-side command signal HS.

The output Q3 of the third flip-flop 273 is set to the Hi when the output C2 of the combinational logic circuit 272 becomes the Hi at time t2 and time t6, and is reset to the Lo when the low-side command signal LS becomes the Hi at time t3. The fourth flip-flop 274 samples the value Lo of Q3 at timings when the high-side command signal HS becomes the Hi at time t1 and time t5, and holds this value as the output Q4. Thereby, when the drain current polarity Idp_LS of the low-side is negative, the output of the low-side determiner 270 is constantly negative (Lo).

As described above, the low-side determiner 270 can determine the drain current polarity Idp_LS of the low-side, based on the high-side command signal HS, the low-side command signal LS, and the voltage Vds_LS between the drain and the source of the low-side.

As described above, the drive circuit 220 of the half-bridge inverter 200 according to Embodiment 2 includes the low-side determiner 270 that determines the drain current polarity Idp_LS of the switching element 12 of the low-side in the half-bridge circuit 10. The low-side determiner 270 determines the drain current polarity Idp_LS of the low-side, based on the voltage Vds_LS between the drain and the source in the switching element 12 of the low-side during the dead time of the half-bridge circuit 10. The sign inverter 221 acquires the drain current polarity Idp_HS of the high-side, by inverting the sign of the drain current polarity Idp_LS of the low-side.

Because of the above characteristic, the drive circuit 220 of the half-bridge inverter 200 according to Embodiment 2 can determine the drain current polarity Idp of each switching element included in the half-bridge circuit 10, from the voltage Vds_LS between the drain and the source in the switching element 12 of the low-side included in the half-bridge circuit 10.

### Embodiment 3

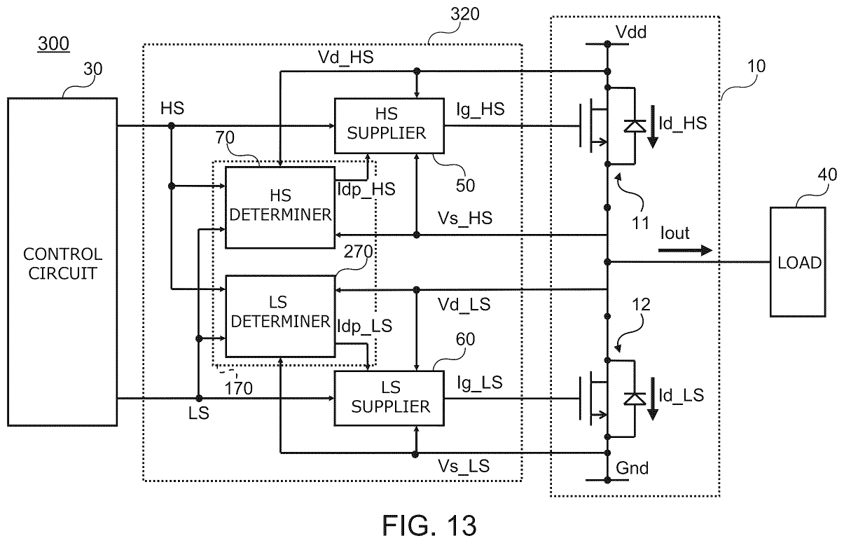

FIG. 13 is a diagram showing the configuration of a half-bridge inverter 300 according to Embodiment 3. A drive circuit 320 includes both the high-side determiner 70 in Embodiment 1 and the low-side determiner 270 in Embodiment 2. The high-side determiner 70 and the low-side determiner 270 constitute a determination circuit (a processing circuitry) 170 that determines the current polarity of at least one of the switching element 11 of the high-side and the switching element 12 of the low-side. Because of such a configuration, in the drive circuit 320, it is possible to exclude the sign inverter included in Embodiments 1 and 2.

In Embodiments 1 and 2, in the case where the high-side supplier 50 and the low-side supplier 60 operate at different reference potentials, when the sign inverter inverts the sign of the drain current polarity Idp, it is necessary to interpose a level shifter, or to transmit a signal in a state where the two are insulated by a photocoupler or the like. In Embodiment 3, it is not necessary to invert the sign of the drain current polarity Idp, and therefore, it is not necessary to perform such measures.

### Embodiment 4

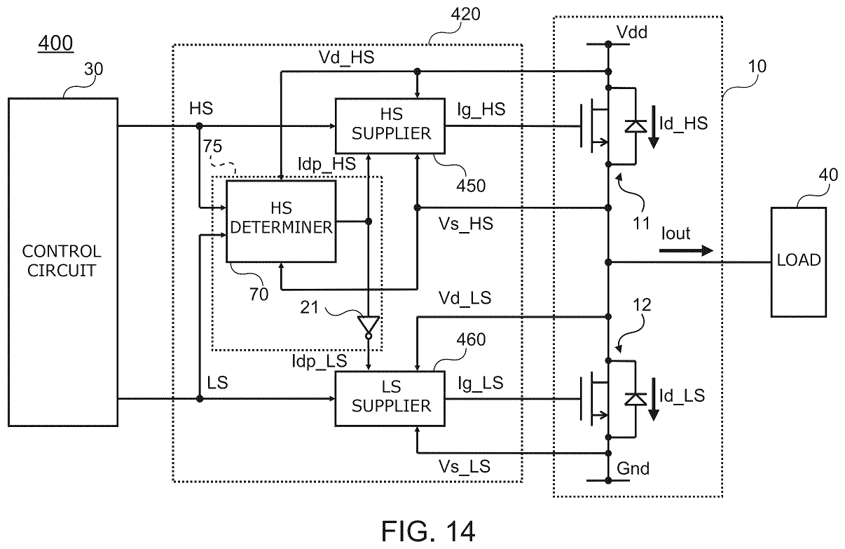

FIG. 14 is a diagram showing the configuration of a half-bridge inverter 400 according to Embodiment 4. A drive circuit 420 includes a high-side supplier 450 and a low-side supplier 460, instead of the high-side supplier 50 and the low-side supplier 60 in Embodiment 1.

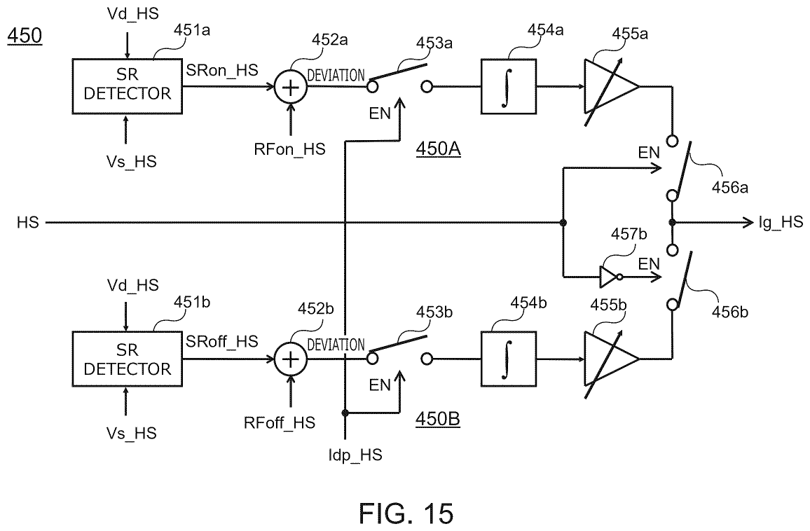

FIG. 15 is a diagram showing the detailed configuration of the high-side supplier 450. The high-side supplier 450 includes a turn-on slew rate detector 451a, an adder 452a, a switch 453a, a compensator 454a, a turn-on current controller 455a, and a switch 456a. These constituent elements constitute a high-side turn-on slew rate controller 450A.

Further, the high-side supplier 450 includes a turn-off slew rate detector 451b, an adder 452b, a switch 453b, a compensator 454b, a turn-off current controller 455b, a switch 456b, and a NOT gate 457b. These constituent elements constitute a high-side turn-off slew rate controller 450B.

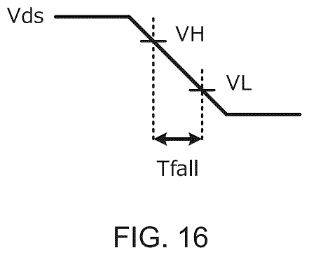

When the drain current polarity Idp_HS of the high-side is positive (Hi) and the high-side command signal HS is the Hi, the high-side turn-on slew rate controller 450A controls the magnitude of the gate current Ig_HS, such that a slew rate SRon_HS at the time of the turn-on of the high-side coincides with a target value RFon_HS. As shown in FIG. 16, the turn-on slew rate detector 451a measures a time Tfall for which the voltage Vds between the drain and the source passes between two thresholds VH, VL at the time of falling, and calculates the turn-on slew rate SRon_HS. An example of the calculation expression is shown below.

$$\begin{matrix}[ Expression 1 ] & \\ SRon\_HS = \frac{V H - V L}{τ f a l l} & ( 1 )\end{matrix}$$

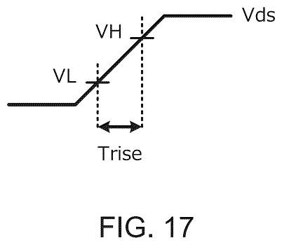

When the drain current polarity Idp_HS of the high-side is positive (Hi) and the high-side command signal HS is the Lo, the high-side turn-off slew rate controller 450B controls the magnitude of the gate current Ig_HS, such that a slew rate SRoff_HS at the time of the turn-off of the high-side coincides with a target value RFoff_HS. As shown in FIG. 17, the turn-off slew rate detector 451b measures a time Trise for which the voltage Vds between the drain and the source passes between the two threshold VL, VH at time of rising, and calculates the turn-off slew rate SRoff_HS. An example of the calculation expression is shown below.

$$\begin{matrix}[ Expression 2 ] & \\ SRoff\_HS = \frac{VH - VL}{Trise} & ( 2 )\end{matrix}$$

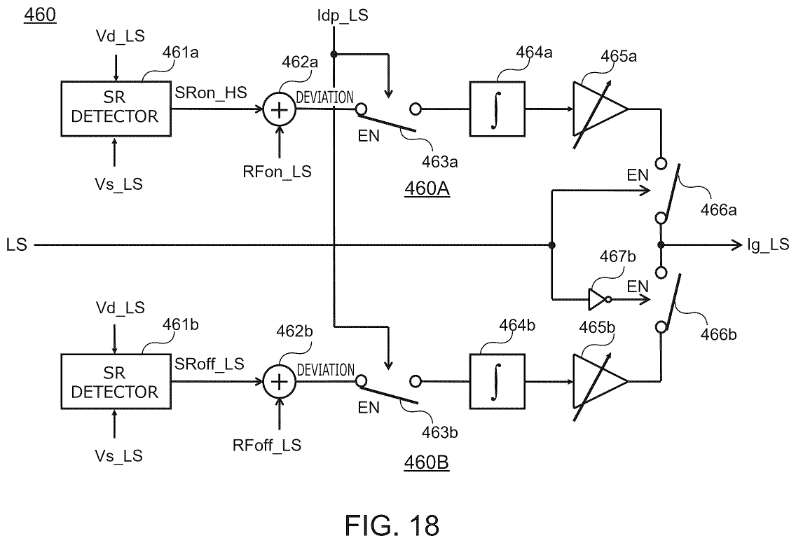

FIG. 18 is a diagram showing the detailed configuration of the low-side supplier 460. The low-side supplier 460 includes a turn-on slew rate detector 461a, an adder 462a, a switch 463a, a compensator 464a, a turn-on current controller 465a, and a switch 466a. These constituent elements constitute a low-side turn-on slew rate controller 460A.

Further, the low-side supplier 460 includes a turn-off slew rate detector 461b, an adder 462b, a switch 463b, a compensator 464b, a turn-off current controller 465b, a switch 466b, and a NOT gate 467b. These constituent elements constitute a low-side turn-off slew rate controller 460B.

When the drain current polarity Idp_LS of the low-side is positive (Hi) and the low-side command signal LS is the Hi, the low-side turn-on slew rate controller 460A controls the magnitude of the gate current Ig_LS, such that a slew rate SRon_LS at the time of the turn-on of the low-side coincides with a target value RFon_LS. The turn-on slew rate detector 461a measures the time Tfall for which the voltage Vds between the drain and the source passes between the two thresholds VH, VL at time of falling, and calculates the turn-on slew rate SRon_LS. An example of the calculation expression is shown below.

$$\begin{matrix}[ Expression 3 ] & \\ SRon\_LS = \frac{V H - V L}{T f a l l} & ( 3 )\end{matrix}$$

When the drain current polarity Idp_LS of the low-side is positive (Hi) and the low-side command signal LS is the Lo, the low-side turn-off slew rate controller 460B controls the magnitude of the gate current Ig_LS, such that a slew rate SRoff_LS at the time of the turn-off of the low-side coincides with a target value RFoff_LS. The turn-off slew rate detector 461b measures the time Trise for which the voltage Vds between the drain and the source passes between the two thresholds VL, VH at the time of rising, and calculates the turn-off slew rate SRoff_LS. An example of the calculation expression is shown below.

$$\begin{matrix}[ Expression 4 ] & \\ SRoff\_LS = \frac{VH - VL}{Trise} & ( 4 )\end{matrix}$$

As described above, in the drive circuit 420 of the half-bridge inverter 400 according to Embodiment 4, the high-side supplier 450 includes the high-side turn-on slew rate controller 460A that controls the slew rate SRon_HS at the time of the turn-on and the high-side turn-off slew rate controller 460B that controls the slew rate SRoff_HS at the time of the turn-off. Similarly, the low-side supplier 460 includes the low-side turn-on slew rate controller 470A that controls the slew rate SRon_LS at the time of the turn-on and the low-side turn-off slew rate controller 470B that controls the slew rate SRoff_HS at the time of the turn-off.

Because of the above characteristic, the drive circuit 420 of the half-bridge inverter 400 according to Embodiment 4 can independently control the turn-on slew rate and the turn-off slew rate of the voltage Vds between the drain and the source of each of the high-side and the low-side.

### Embodiment 5

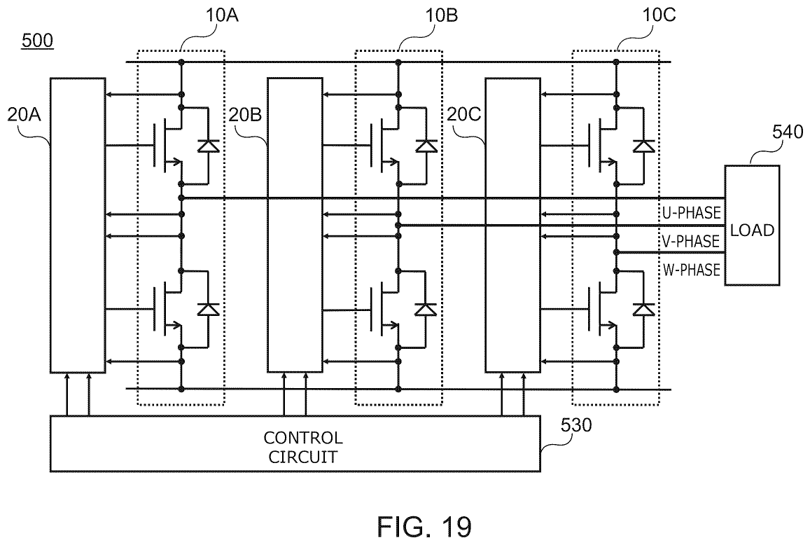

FIG. 19 is a diagram showing the configuration of a three-phase inverter 500 according to Embodiment 5. The three-phase inverter 500 includes three half-bridge circuits 10A to 10C, three drive circuits 20A to 20C, and a control circuit 530. A load 540 is connected to outputs of the three-phase inverter 500. Each of the half-bridge circuits 10A to 10C has the same configuration as the half-bridge circuit 10 in Embodiment 1. Each of the drive circuits 20A to 20C has the same configuration as the drive circuit 20 in Embodiment 1.

The control circuit 530 supplies the high-side command signal HS and the low-side command signal LS to each of the drive circuits 20A to 20C. The load 540 is an arbitrary electronic device or electric device that is driven by three-phase alternating-current power. For example, in the case where the load 540 is a three-phase alternating-current motor, the control circuit 530 supplies the high-side command signal HS and low-side command signal LS after PWM modulation, to each of the drive circuits 20A to 20C.

As another application example, an inverter including the drive circuit 20A, the half-bridge circuit 10A, and the control circuit 530 may be used as a PV inverter for solar photovoltaic generation. In this case, the output of the PV inverter is connected to an electric power grid.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The embodiments of the present invention can also be configured as follows.

### Clauses

Clause 1. An electronic circuitry comprising:
a processing circuitry configured to determine a current polarity being a polarity of a current flowing through at least one of a first switching element and a second switching element, based on a first voltage between a first electrode and a second electrode of the first switching element during a dead time of a half-bridge circuit, the half-bridge circuit including the first switching element and the second switching element.

Clause 2. The electronic circuitry according to Clause 1, wherein
the processing circuitry determines whether the half-bridge circuit is in the dead time, based on a first command signal for controlling a switching operation of the first switching element and a second command signal for controlling a switching operation of the second switching element.

Clause 3. The electronic circuitry according to Clause 1, wherein
the processing circuitry includes
   a first determiner configured to determine a first current polarity of the first switching element based on the first voltage; and
   a sign inverter configured to invert a sign of the first current polarity to acquire a second current polarity of the second switching element.

Clause 4. The electronic circuitry according to Clause 1, wherein
the processing circuitry includes
   a first determiner configured to determine a first current polarity of the first switching element based on the first voltage; and
   a second determiner configured to determine a second current polarity of the second switching element based on a second voltage between a third electrode and a fourth electrode of the second switching element during the dead time.

Clause 5. The electronic circuitry according to Clause 3 or 4, wherein
the first switching element is provided at a high-side of the half-bridge circuit;
the electronic circuitry further comprises a voltage division circuit configured to divide the first voltage and generate a logic signal;
the first determiner includes
a combinational logic circuit receiving a first command signal, a second command signal, and the logic signal as inputs,
   the first command signal being a signal for controlling switching operation of the first switching element and
   the second command signal being a signal for controlling switching operation of the second switching element,
a first sequence circuit, and
a second sequence circuit;
the combinational logic circuit outputs a first logic level when the half-bridge circuit is in the dead time and the first voltage corresponds to a supply voltage;
the first sequence circuit is set to the first logic level when an output of the combinational logic circuit becomes the first logic level, and is reset to a second logic level when the first command signal becomes the first logic level; and
the second sequence circuit samples an output of the first sequence circuit when the second command signal becomes the first logic level, the sampled output indicating the first current polarity of the first switching element.

Clause 6. The electronic circuitry according to Clause 3 or 4, wherein
the first switching element is provided at a low-side of the half-bridge circuit;
the electronic circuitry further comprises a voltage division circuit configured to divide the first voltage and generate a logic signal;
the first determiner includes
a combinational logic circuit receiving a first command signal, a second command signal, and the logic signal as inputs,
   the first command signal being a signal for controlling switching operation of the first switching element and
   the second command signal being a signal for controlling switching operation of the second switching element,
a third sequence circuit, and
a fourth sequence circuit;
the combinational logic circuit outputs a first logic level when the half-bridge circuit is in the dead time and the first voltage corresponds to a supply voltage;
the third sequence circuit is set to the first logic level when an output of the combinational logic circuit becomes the first logic level, and is reset to a second logic level when the second command signal becomes the first logic level; and
the fourth sequence circuit samples an output of the third sequence circuit when the first command signal becomes the first logic level, the sampled output indicating the first current polarity of the first switching element.

Clause 7. A drive circuit for a half-bridge circuit that includes a first switching element and a second switching element, the drive circuit comprising:
a first supplier configured to supply a first drive current to the first switching element;
a second supplier configured to supply a second drive current to the second switching element; and
a processing circuitry configured to determine a current polarity being a polarity of a current flowing through at least one of the first switching element and the second switching element, based on a first voltage between a first electrode and a second electrode of the first switching element during a dead time of the half-bridge circuit.

Clause 8. The drive circuit according to Clause 7, wherein
the current polarity includes a first current polarity of the first switching element; and
the first supplier includes a first slew rate controller configured to control a slew rate of the first voltage based on the first current polarity.

Clause 9. The drive circuit according to Clause 8, wherein
the first slew rate controller controls the slew rate of the first voltage when the first current polarity is positive, and does not control the slew rate of the first voltage when the first current polarity is negative.

Clause 10. The drive circuit according to Clause 8, wherein
the first slew rate controller includes
   a first turn-on slew rate controller configured to control the slew rate of the first voltage during turn-on based on the first current polarity and
   a first turn-off slew rate controller configured to control the slew rate of the first voltage during turn-off based on the first current polarity.

Clause 11. The drive circuit according to Clause 7, wherein
the current polarity includes a second current polarity of the second switching element; and
the second supplier includes a second slew rate controller configured to control a slew rate of a second voltage between a third electrode and a fourth electrode of the second switching element, based on the second current polarity.

Clause 12. The drive circuit according to Clause 11, wherein
the processing circuitry determines a first current polarity of the first switching element based on the first voltage; and
the processing circuitry includes a sign inverter configured to invert a sign of the first current polarity and acquire a second current polarity of the second switching element.

Clause 13. The drive circuit according to Clause 11, wherein
the second slew rate controller controls the slew rate of the second voltage when the second current polarity is positive, and does not control the slew rate of the second voltage when the second current polarity is negative.

Clause 14. The drive circuit according to Clause 11, wherein
the second slew rate controller includes
   a second turn-on slew rate controller configured to control the slew rate of the second voltage during turn-on based on the second current polarity and
   a second turn-off slew rate controller configured to control the slew rate of the second voltage during turn-off based on the second current polarity.

Clause 15. A three-phase inverter comprising:
first to third half-bridge circuits each including a first switching element and a second switching element; and
first to third drive circuits, each including is the drive circuit according to Clause 7, the first to third drive circuits respectively driving the first to third half-bridge circuits.

Clause 16. A determination method comprising:
determining a current polarity being a polarity of a current flowing through at least one of a first switching element and a second switching element, based on a first voltage between a first electrode and a second electrode of the first switching element during a dead time of a half-bridge circuit, the half-bridge circuit including the first switching element and the second switching element.

1. An electronic circuitry comprising:
a processing circuitry configured to determine a current polarity being a polarity of a current flowing through at least one of a first switching element and a second switching element, based on a first voltage between a first electrode and a second electrode of the first switching element during a dead time of a half-bridge circuit, the half-bridge circuit including the first switching element and the second switching element.

2. The electronic circuitry according to claim 1, wherein
the processing circuitry determines whether the half-bridge circuit is in the dead time, based on a first command signal for controlling a switching operation of the first switching element and a second command signal for controlling a switching operation of the second switching element.

3. The electronic circuitry according to claim 1, wherein
the processing circuitry includes
a first determiner configured to determine a first current polarity of the first switching element based on the first voltage; and
a sign inverter configured to invert a sign of the first current polarity to acquire a second current polarity of the second switching element.

4. The electronic circuitry according to claim 1, wherein
the processing circuitry includes
a first determiner configured to determine a first current polarity of the first switching element based on the first voltage; and
a second determiner configured to determine a second current polarity of the second switching element based on a second voltage between a third electrode and a fourth electrode of the second switching element during the dead time.

5. The electronic circuitry according to claim 3, wherein
the first switching element is provided at a high-side of the half-bridge circuit;
the electronic circuitry further comprises a voltage division circuit configured to divide the first voltage and generate a logic signal;
the first determiner includes
a combinational logic circuit receiving a first command signal, a second command signal, and the logic signal as inputs,
the first command signal being a signal for controlling switching operation of the first switching element and
the second command signal being a signal for controlling switching operation of the second switching element,
a first sequence circuit, and
a second sequence circuit;
the combinational logic circuit outputs a first logic level when the half-bridge circuit is in the dead time and the first voltage corresponds to a supply voltage;
the first sequence circuit is set to the first logic level when an output of the combinational logic circuit becomes the first logic level, and is reset to a second logic level when the first command signal becomes the first logic level; and
the second sequence circuit samples an output of the first sequence circuit when the second command signal becomes the first logic level, the sampled output indicating the first current polarity of the first switching element.

6. The electronic circuitry according to claim 3, wherein
the first switching element is provided at a low-side of the half-bridge circuit;
the electronic circuitry further comprises a voltage division circuit configured to divide the first voltage and generate a logic signal;
the first determiner includes
a combinational logic circuit receiving a first command signal, a second command signal, and the logic signal as inputs,
the first command signal being a signal for controlling switching operation of the first switching element and
the second command signal being a signal for controlling switching operation of the second switching element,
a third sequence circuit, and
a fourth sequence circuit;
the combinational logic circuit outputs a first logic level when the half-bridge circuit is in the dead time and the first voltage corresponds to a supply voltage;
the third sequence circuit is set to the first logic level when an output of the combinational logic circuit becomes the first logic level, and is reset to a second logic level when the second command signal becomes the first logic level; and
the fourth sequence circuit samples an output of the third sequence circuit when the first command signal becomes the first logic level, the sampled output indicating the first current polarity of the first switching element.

7. A drive circuit for a half-bridge circuit that includes a first switching element and a second switching element, the drive circuit comprising:
a first supplier configured to supply a first drive current to the first switching element;
a second supplier configured to supply a second drive current to the second switching element; and
a processing circuitry configured to determine a current polarity being a polarity of a current flowing through at least one of the first switching element and the second switching element, based on a first voltage between a first electrode and a second electrode of the first switching element during a dead time of the half-bridge circuit.

8. The drive circuit according to claim 7, wherein
the current polarity includes a first current polarity of the first switching element; and
the first supplier includes a first slew rate controller configured to control a slew rate of the first voltage based on the first current polarity.

9. The drive circuit according to claim 8, wherein
the first slew rate controller controls the slew rate of the first voltage when the first current polarity is positive, and does not control the slew rate of the first voltage when the first current polarity is negative.

10. The drive circuit according to claim 8, wherein
the first slew rate controller includes
a first turn-on slew rate controller configured to control the slew rate of the first voltage during turn-on based on the first current polarity and
a first turn-off slew rate controller configured to control the slew rate of the first voltage during turn-off based on the first current polarity.

11. The drive circuit according to claim 7, wherein
the current polarity includes a second current polarity of the second switching element; and
the second supplier includes a second slew rate controller configured to control a slew rate of a second voltage between a third electrode and a fourth electrode of the second switching element, based on the second current polarity.

12. The drive circuit according to claim 11, wherein
the processing circuitry determines a first current polarity of the first switching element based on the first voltage; and
the processing circuitry includes a sign inverter configured to invert a sign of the first current polarity and acquire a second current polarity of the second switching element.

13. The drive circuit according to claim 11, wherein
the second slew rate controller controls the slew rate of the second voltage when the second current polarity is positive, and does not control the slew rate of the second voltage when the second current polarity is negative.

14. The drive circuit according to claim 11, wherein
the second slew rate controller includes
a second turn-on slew rate controller configured to control the slew rate of the second voltage during turn-on based on the second current polarity and
a second turn-off slew rate controller configured to control the slew rate of the second voltage during turn-off based on the second current polarity.

15. A three-phase inverter comprising:
first to third half-bridge circuits each including a first switching element and a second switching element; and
first to third drive circuits, each including is the drive circuit according to claim 7, the first to third drive circuits respectively driving the first to third half-bridge circuits.

16. A determination method comprising:
determining a current polarity being a polarity of a current flowing through at least one of a first switching element and a second switching element, based on a first voltage between a first electrode and a second electrode of the first switching element during a dead time of a half-bridge circuit, the half-bridge circuit including the first switching element and the second switching element.
